(19) United States
(12) Patent Application Publication
(10) Pub. No.: US 2024/0393702 A1
(43) Pub. Date: Nov. 28, 2024

(54) SUBSTRATE PROCESSING APPARATUS, SUBSTRATE PROCESSING METHOD AND ARTICLE MANUFACTURING METHOD

(71) Applicant: CANON KABUSHIKI KAISHA, Tokyo (JP)

(72) Inventors: RYOTA MAKINO, Tochigi (JP); KAZUYA KIJIMA, Tochigi (JP)

(21) Appl. No.: 18/663,328

(22) Filed: May 14, 2024

(30) Foreign Application Priority Data
May 24, 2023 (JP) 2023-085705

(51) Int. Cl. G03F 7/00; H01L 21/677

(52) U.S. Cl. CPC G03F 7/70733; G03F 7/70875; H01L 21/677

(57) ABSTRACT

A substrate processing apparatus for performing a process of a substrate, including a substrate stage configured to hold a substrate when the process is performed, a temperature control mechanism configured to hold a substrate to be conveyed to the substrate stage and perform temperature control to a predetermined temperature, a conveyance mechanism configured to convey a substrate in the apparatus, and a control unit configured to control conveyance of a substrate in the apparatus, wherein when a waiting time until the substrate conveyed to a supply position is supplied to the substrate stage exceeds an upper limit time set in advance, the control unit conveys the substrate from the supply position to the temperature control mechanism by the conveyance mechanism.

### BACKGROUND OF THE INVENTION

### Field of the Invention

The present invention relates to a substrate processing apparatus, a substrate processing method and an article manufacturing method.

### Description of the Related Art

In an exposure apparatus or a measurement apparatus which is used in the manufacturing process of a device such as a semiconductor element or a liquid crystal display element, substrate alignment and substrate temperature control (adjustment to a predetermined temperature) are generally executed before conveying a substrate to be processed to a substrate stage (substrate holding unit). In recent years, along with micropatterning and higher integration of devices, demands for improving the alignment accuracy and the overlay accuracy are growing. Accordingly, more strict management (control) is required for the temperature of the substrate.

Japanese Patent No. 5708310 proposes a technique concerning substrate temperature control. Japanese Patent No. 5708310 discloses a technique for reducing the influence of the temperature of a conveyance space on the substrate in a conveyance step of conveying the substrate to a processing space. This technique controls the temperature of the substrate in a temperature control unit based on the temperature of the conveyance space to bring the temperature of the substrate to a predetermined temperature at the timing immediately before the substrate arrives the processing space.

In the manufacturing process of a device, when continuously processing substrates from the viewpoint of throughput, a plurality of substrates exist in the apparatus. In this case, when exchanging the preceding substrate and the succeeding substrate with respect to a substrate stage, the succeeding substrate is made to wait in advance by holding it with a conveyance hand located in a substrate exchange position. This can suppress the time required for substrate exchange (exchange between the preceding substrate and the succeeding substrate), thereby improving throughput.

Here, considering the technique disclosed in Japanese Patent No. 5708310, the temperature of the succeeding substrate is adjusted (controlled) to the predetermined temperature through the temperature control unit before being located in the substrate exchange position. However, while waiting in the substrate exchange position, the temperature of the succeeding substrate fluctuates mainly due to the influence of the ambient temperature in the substrate exchange position and shifts from the predetermined temperature. The time (waiting time) for the succeeding substrate waiting in the substrate exchange position depends on the time (processing time) required for the process performed on the preceding substrate. The processing time of the preceding substrate varies depending on presence/absence of calibration performed at the beginning of a lot, a substrate alignment error, a substrate alignment retry, and the like. Therefore, the time until the substrate is conveyed from the temperature control unit to the substrate stage differs between substrates in a lot, and fluctuation and variation of the substrate temperature caused by the time difference lead to deterioration of the alignment accuracy and the overlay accuracy.

### SUMMARY OF THE INVENTION

The present invention provides a technique advantageous in reducing variation of the temperature of a substrate upon supplying the substrate to a substrate stage.

According to one aspect of the present invention, there is provided a substrate processing apparatus for performing a process of a substrate, including a substrate stage configured to hold a substrate when the process is performed, a temperature control mechanism configured to hold a substrate to be conveyed to the substrate stage and perform temperature control to a predetermined temperature, a conveyance mechanism configured to convey a substrate in the apparatus, and a control unit configured to control conveyance of a substrate in the apparatus, wherein when a first time required to convey, by the conveyance mechanism, a first substrate having undergone temperature control by the temperature control mechanism from the temperature control mechanism to a supply position where a substrate is supplied to the substrate stage becomes not less than a second time required to drive the substrate stage holding a second substrate, on which the process is being performed prior to the first substrate, to the supply position via a collection position where the processed substrate is collected, the control unit starts conveyance of the first substrate from the temperature control mechanism to the substrate stage by the conveyance mechanism, and when a waiting time until the first substrate conveyed to the supply position is supplied to the substrate stage exceeds an upper limit time set in advance, the control unit conveys the first substrate from the supply position to the temperature control mechanism by the conveyance mechanism.

Further aspects of the present invention will become apparent from the following description of exemplary embodiments with reference to the attached drawings.

### BRIEF DESCRIPTION OF THE DRAWINGS

FIGS. 1A and 1B are views for describing an exposure apparatus according to an aspect of the present invention.

FIGS. 2A and 2B are views for describing conveyance of a substrate in the exposure apparatus.

FIG. 3 is a flowchart for describing a conveyance process.

FIG. 4 is a flowchart for describing a substrate process.

FIG. 5 is a view showing the shot layout of the substrate.

FIG. 6 is a flowchart for describing a conveyance process.

FIG. 7 is a flowchart for describing a substrate process.

FIGS. 8A and 8B are views for describing the conveyance process illustrated in FIG. 6.

FIGS. 9A and 9B are views for describing a measurement apparatus according to an aspect of the present invention.

FIG. 10 is a flowchart for describing a substrate process.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

In this embodiment, a substrate processing apparatus that processes a substrate includes a lithography apparatus, a measurement apparatus, an inspection apparatus, and the like. The lithography apparatus includes, for example, an exposure apparatus, an imprint apparatus, a planarization apparatus, a drawing apparatus, and the like. The exposure apparatus includes an apparatus that projects the pattern of an original (mask or reticle) to a substrate and exposes the substrate. The imprint apparatus includes an apparatus that forms a pattern of an imprint material on a substrate by molding the imprint material on the substrate with a mold. The planarization apparatus includes an apparatus that planarizes a composition on a substrate using a mold having a flat surface. The drawing apparatus includes an apparatus that draws a pattern on a substrate using a charged particle beam (such as an electron beam or an ion beam). The measurement apparatus includes an alignment measurement apparatus used for alignment between an original and a substrate. The inspection apparatus includes an overlay inspection apparatus that inspects the overlay accuracy of a pattern formed on a substrate.

### First Embodiment

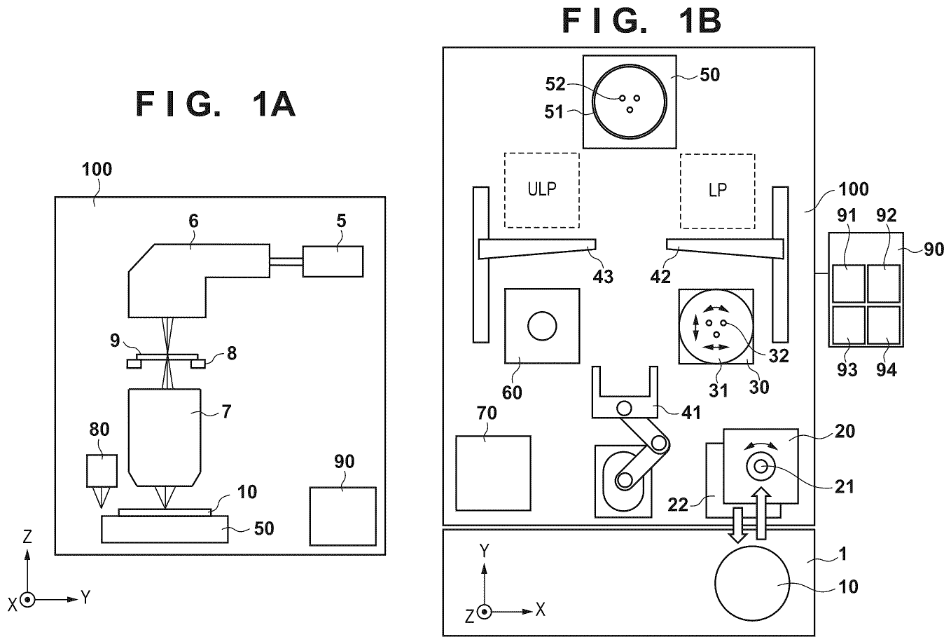

FIGS. 1A and 1B are views for describing an exposure apparatus 100 as a substrate processing apparatus in the first embodiment of the present invention. The exposure apparatus 100 is used in a lithography process as a manufacturing process of a device such as a semiconductor element or a liquid crystal display element. The exposure apparatus 100 is a lithography apparatus that exposures a substrate using an original, thereby transferring the pattern of the original to the substrate, that is, forming the pattern on the substrate.

As shown in FIG. 1A, the exposure apparatus 100 includes an illumination optical system 6, a projection optical system 7, an original stage 8, a substrate stage 50, an alignment optical system 80, and a control unit 90.

The illumination optical system 6 shapes light (exposure light) from a light source unit 5 into a predetermined shape suitable for exposure, and uniformly illuminates an original 9 with this light. The original 9 is made of, for example, quartz. The original 9 is formed with a pattern (circuit pattern) to be transferred to a substrate 10.

The original stage 8 holds the original 9 via an original chuck, and is driven by an original driving mechanism. The original driving mechanism includes a linear motor and the like, and drives the original stage 8 in X, Y, and Z directions and rotation directions for the respective directions, thereby positioning the original 9 held by the original stage 8 at a predetermined position.

The projection optical system 7 is an optical system that has a function of forming, on an image plane, an image of light from an object plane. The projection optical system 7 projects light (diffracted light) having passed through the original 9 (pattern thereof) to the substrate 10, thereby forming an image of the pattern of the original 9 on the substrate. The substrate 10 is a processing target object to which the pattern of the original 9 is transferred, and includes a wafer, a liquid crystal substrate, another processing target substrate, and the like. A photosensitive agent (photoresist) is arranged (coated) on the substrate 10.

The substrate stage 50 holds the substrate 10 via a substrate chuck 51, and is driven by a substrate driving mechanism. The substrate driving mechanism includes a linear motor and the like, and drives the substrate stage 50 in X, Y, and Z directions and rotation directions for the respective directions, thereby positioning the substrate 10 held by the substrate stage 50 at a predetermined position.

The position of the original stage 8 and the position of the substrate stage 50 are monitored (measured) by, for example, a 6-axis laser interferometer or the like, and the original stage 8 and the substrate stage 50 are driven at a constant speed ratio under the control of the control unit 90.

The alignment optical system 80 has a function as a measurement device that detects an alignment mark provided in the substrate 10 and measures the position of the alignment mark (that is, measures the position of the substrate 10). In the exposure apparatus 100, when performing overlay exposure with respect to a target layer on the substrate, the alignment optical system 80 detects the alignment mark provided in the substrate 10 and measures the position of the substrate 10 prior to the exposure.

The control unit 90 is formed by, for example, a computer (information processing apparatus) including a CPU, a memory, and the like. The control unit 90 operates the exposure apparatus 100 by comprehensively controlling respective units of the exposure apparatus 100 in accordance with a program stored in a storage unit or the like.

In the exposure apparatus 100, light having passed through the original 9 is projected to the substrate 10 via the projection optical system 7. The original 9 and the substrate 10 are arranged in an optically conjugate relationship. The pattern of the original 9 is transferred to the substrate 10 by scanning the original 9 and the substrate 10 at a speed ratio of a projection magnification ratio of the projection optical system 7.

Here, with reference to FIG. 1B, the sequence of conveyance of the substrate 10 between the exposure apparatus 100 and a coating/developing apparatus 1 (coater/developer) will be described. Note that the sequence of conveyance of the substrate 10 is, more specifically, the sequence of loading (supplying) the substrate 10 from the coating/developing apparatus 1 to the exposure apparatus 100 and unloading the substrate 10 from the exposure apparatus 100 to the coating/developing apparatus 1. The exposure apparatus 100 is connected to the coating/developing apparatus 1 that has a function of coating a photosensitive agent on the substrate 10 and a function of developing the exposed substrate 10 (the photosensitive agent on the substrate). Connection between the exposure apparatus 100 and the coating/developing apparatus 1 is usually called in-line connection.

The exposure apparatus 100 incudes a conveyance mechanism (conveyance robot) that holds the substrate 10 with a hand and conveys it between the exposure apparatus 100 and the coating/developing apparatus 1 and in the exposure apparatus. In this embodiment, the conveyance mechanism includes a first conveyance mechanism 41, a second conveyance mechanism 42, and a third conveyance mechanism 43.

When loading the substrate 10 from the coating/developing apparatus 1 to the exposure apparatus 100, the substrate 10 is conveyed to an alignment mechanism 20 serving as an interface unit between the exposure apparatus 100 and the coating/developing apparatus 1. The alignment mechanism 20 includes a holding unit 21 that holds the substrate 10, for example, holds the central portion of the substrate 10 from below, and has a function of aligning the substrate 10. The alignment mechanism 20 performs alignment of the substrate 10 in a rotation direction by rotating the holding unit 21 holding the substrate 10 about the Z-axis. The alignment mechanism 20 aligns (rotates) the substrate 10 held by the holding unit 21 such that a notch (or orientation flat) serving as the reference position of the substrate 10 faces a predetermined direction. Here, the predetermined direction means that, when the substrate 10 is conveyed to a temperature control mechanism 30, the notch of the substrate 10 is located within a detection range of a detection sensor provided in the temperature control mechanism 30.

The substrate 10 aligned by the alignment mechanism 20 is conveyed to the temperature control mechanism 30 via the first conveyance mechanism 41. The temperature control mechanism 30 includes a holding unit 33 that holds the substrate 10, a temperature control unit 31 that adjusts (temperature-controls) the substrate 10 (temperature thereof) held by the holding unit 33 to a predetermined temperature, and lift pins 32 used to convey the substrate 10. Note that as shown in FIG. 1B, three lift pins 32 are provided, but the number of the lift pins 32 is not particularly limited as long as the purpose of raising and lowering the substrate 10 while holding it is achieved. The temperature control mechanism 30 also includes a detection sensor (not shown) that detects the notch or outer peripheral shape of the substrate 10 held by the holding unit 33, a driving mechanism (not shown) that drives the holding unit 33 to align the substrate 10 in the rotation directions about the X direction, the Y direction, and the Z-axis, and the like.

In the temperature control mechanism 30, the lift pins 32 are raised from the holding unit 33, and the substrate 10 is received by the lift pins 32 from the first conveyance mechanism 41. Then, by lowering the lift pins 32, the substrate 10 is passed from the lift pins 32 to the holding unit 33, and the holding unit 33 holds (chucks) the substrate 10. The substrate 10 held by the holding unit 33 is adjusted to the predetermined temperature by the temperature control unit 31. More specifically, under the control of the control unit 90, the temperature control unit 31 controls the temperature of the substrate 10 held by the holding unit 33 in accordance with a temperature control profile set (stored) in the control unit 90 and including conditions such as a temperature control time required to adjust the substrate 10 to the predetermined temperature. In this embodiment, the control unit 90 also functions as a temperature control setting unit 92 that implements a function of setting the temperature control profile including various conditions required to adjust the temperature of the substrate 10 to the predetermined temperature, a function of supplying the temperature control profile to the temperature control unit 31, and the like.

Furthermore, in the temperature control mechanism 30, when the substrate 10 is held by the holding unit 33, alignment of the substrate 10 is also performed by driving the holding unit 33 by the driving mechanism based on the notch or outer peripheral shape of the substrate 10 detected by the detection sensor. More specifically, alignment of the substrate 10 in the rotation directions about the X direction, the Y direction, and the Z-axis is performed such that the output from the detection sensor becomes a predetermined output. Here, the predetermined output means that, when the substrate 10 is conveyed to the substrate stage 50, the alignment mark provided in the substrate 10 is located within the detection range of the alignment optical system 80.

In this manner, in the temperature control mechanism 30, temperature control of the substrate 10 and alignment of the substrate 10 are performed in parallel. When temperature control of the substrate 10 and alignment of the substrate 10 are completed, conveyance of the substrate 10 from the temperature control mechanism 30 to the substrate stage 50 is started.

The substrate 10 having undergone the temperature control and alignment by the temperature control mechanism 30 is passed from the holding unit 33 to the lift pins 32 by raising the lift pins 32. The substrate 10 held by the lift pins 32 is passed to the second conveyance mechanism 42. The substrate 10 held by the second conveyance mechanism 42 is conveyed to a supply position LP (above the supply position LP). On the other hand, the substrate stage 50 is driven to the supply position LP, lift pins 52 are raised from the substrate chuck 51, and the substrate 10 is received by the lift pins 52 from the second conveyance mechanism 42. The second conveyance mechanism 42 having passed the substrate 10 to the lift pins 52 retreats from the supply position LP. In the substrate stage 50, by lowering the lift pins 52, the substrate 10 is passed from the lift pins 52 to the substrate chuck 51, and the substrate chuck 51 holds (chucks) the substrate 10.

When the substrate 10 is held by the substrate stage 50 via the substrate chuck 51, an exposure sequence is started. The exposure sequence mainly includes an alignment process and an exposure process. The alignment process is a process of obtaining the position of the substrate 10 (shot region (underlying pattern) thereof) by detecting the alignment mark provided in the substrate 10 by the alignment optical system 80 (so-called global alignment). The exposure process is a process of projecting the pattern of the original 9 to the substrate 10 via the projection optical system 7 and transferring the pattern of the original to the substrate, that is, forming the pattern on the substrate.

When the exposure sequence is completed, the substrate stage 50 is driven to a collection position ULP, and the substrate 10 held by the substrate stage 50 is passed to the third conveyance mechanism 43. The substrate 10 held by the third conveyance mechanism 43 is conveyed to a collection table 60. The substrate 10 conveyed to the collection table 60 is collected (held) by the first conveyance mechanism 41, and unloaded to an unloading table 22 serving as an interface unit between the exposure apparatus 100 and the coating/developing apparatus 1. The substrate 10 conveyed to the unloading table 22 is collected by a conveyance mechanism provided in the coating/developing apparatus 1, and a development process of developing the substrate 10 is performed.

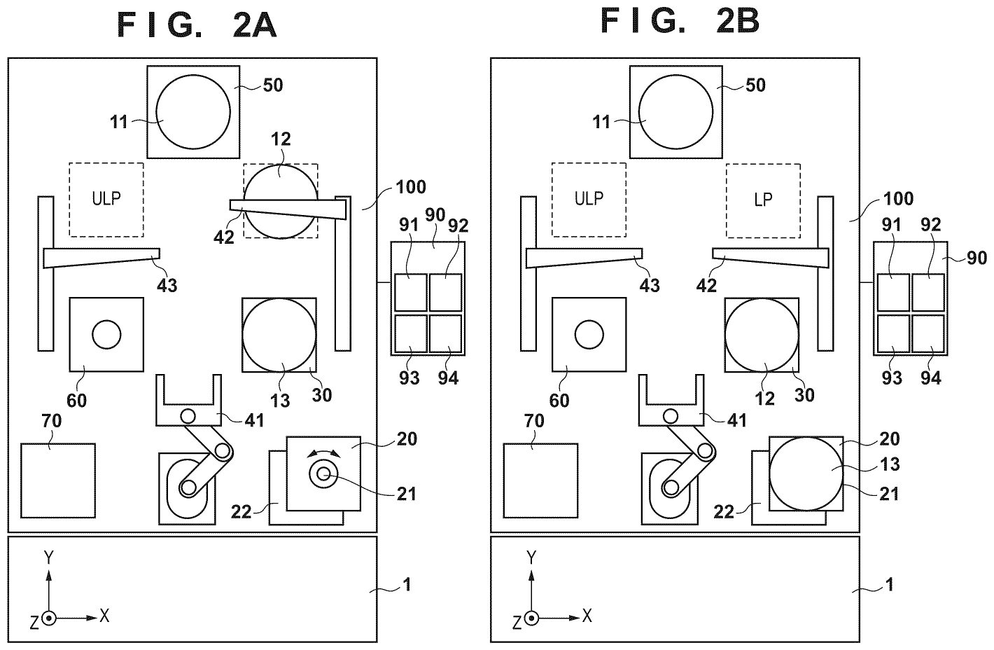

In a substrate processing apparatus including the exposure apparatus 100, in general, the process (the exposure sequence including the exposure process and the alignment process) with respect to the substrate 10 held by the substrate stage 50 takes the most time. In a conventional technique, as shown in FIG. 2A, when the process with respect to an (N−1)th substrate 11 (second substrate) held by the substrate stage 50 is completed, an Nth substrate 12 (first substrate) can be immediately supplied (conveyed) to the substrate stage 50. More specifically, the second conveyance mechanism 42 holding the Nth substrate 12 is driven to the supply position LP, thereby making the Nth substrate 12 wait in the supply position LP. Note that Nis an arbitrary number equal to or lager than 2, and indicates the order (conveyance order) of substrates loaded from the coating/developing apparatus 1 to the exposure apparatus 100.

However, in the exposure apparatus 100, if the Nth substrate 12 is made to wait in the supply position LP, depending on the ambient temperature in the waiting space (the temperature in the supply position LP), the temperature of the Nth substrate 12 having undergone the temperature control by the temperature control mechanism 30 shifts from the predetermined temperature. The time (waiting time) to keep the Nth substrate 12 waiting in the supply position LP fluctuates in accordance with the time (processing time) required for the process with respect to the (N−1)th substrate 11. Therefore, if the substrate 10 is kept waiting in the supply position LP, it is difficult to control (manage) the temperature of the substrate 10 upon supplying (passing) the substrate 10 to the substrate stage 50 to be constant (predetermined temperature) among the substrates in a lot. Such variation of the temperature of the substrate 10 affects the alignment accuracy and the overlay accuracy in the exposure apparatus 100.

To solve this problem, in this embodiment, as shown in FIG. 2B, even after the temperature control and alignment of the substrate 10 by the temperature control mechanism 30 are completed, the substrate 10 is not conveyed to the supply position LP but the temperature control mechanism 30 (holding unit 33) continues to hold the substrate 10. More specifically, while the process with respect to the (N−1)th substrate 11 held by the substrate stage 50 is performed, the Nth substrate 12 is made to wait in the temperature control mechanism 30 until the condition (conveyance start condition) for starting conveyance of the Nth substrate 12 is satisfied.

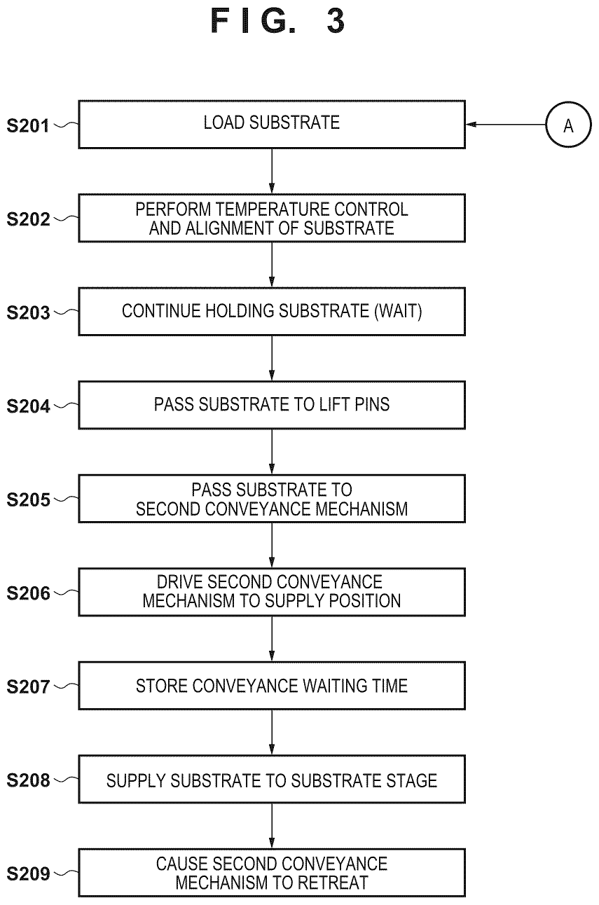

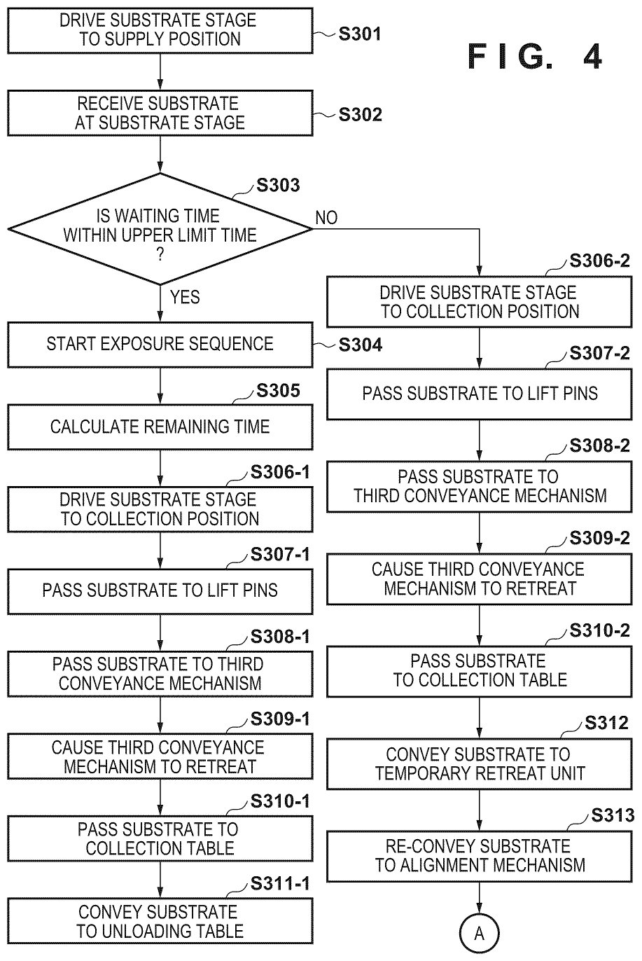

With reference to FIGS. 3 and 4, a specific conveyance sequence (conveyance method) of the substrate 10 between the exposure apparatus 100 and the coating/developing apparatus 1 in this embodiment will be described. FIG. 3 is a flowchart for describing a process (conveyance process) from loading the substrate 10 from the coating/developing apparatus 1 to the exposure apparatus 100 to conveying the substrate 10 to the substrate stage 50. FIG. 4 is a flowchart for describing a process (substrate process) of holding the substrate 10 by the substrate stage 50 and performing exposure. As has been described above, the conveyance process and the substrate process are performed by comprehensively controlling respective units of the exposure apparatus 100 by the control unit 90.

First, the conveyance process illustrated in FIG. 3 will be described. In step S201, the substrate 10 is loaded from the coating/developing apparatus 1 to the exposure apparatus 100. The substrate 10 loaded to the exposure apparatus 100 is conveyed via the alignment mechanism 20 to the temperature control mechanism 30 by the first conveyance mechanism 41.

In step S202, the temperature control mechanism 30 performs temperature control and alignment of the substrate 10. The substrate 10 conveyed to the temperature control mechanism 30 is held by the holding unit 33. In the temperature control mechanism 30, while the substrate 10 held by the holding unit 33 is adjusted to the predetermined temperature by the temperature control unit 31, the substrate 10 is aligned by driving the holding unit 33 by the driving mechanism (temperature control and alignment of the substrate 10 are performed in parallel).

In step S203, even after the temperature control and alignment of the substrate 10 in step S202 are completed, the temperature control mechanism 30 continues to hold the substrate 10. In other words, the substrate 10 completed with the temperature control and alignment in step S202 is made to wait in the temperature control mechanism 30. At this time, the temperature control mechanism 30 continues the temperature control of the substrate 10 to maintain the temperature of the substrate 10 at the predetermined temperature. As has been described above, holding (waiting) of the substrate 10 in the temperature control mechanism 30 is continued until the conveyance start condition for starting conveyance of the substrate 10 to the substrate stage 50 is satisfied. FIG. 2B shows the state corresponding to step S203, where the Nth substrate 12 (first substrate) is held by the temperature control mechanism 30 (holding unit 33) and the (N−1)th substrate 11 (second substrate) is held by the substrate stage 50 (substrate chuck 51). The following description assumes that the conveyance start condition is satisfied.

In step S204, in order to convey the substrate 10 (Nth substrate 12) from the temperature control mechanism 30 to the substrate stage 50, the substrate 10 held by the holding unit 33 is passed to the lift pins 32 in the temperature control mechanism 30. More specifically, holding of the substrate 10 by the holding unit 33 is canceled (OFF), and the lift pins 32 are raised (driven in the +Z direction). With this, the substrate 10 is passed from the holding unit 33 to the lift pins 32, and the lift pins 32 hold the substrate 10.

In step S205, the substrate 10 held by the lift pins 32 is passed to the second conveyance mechanism 42. More specifically, first, the second conveyance mechanism 42 is driven and inserted between the holding unit 33 and the lift pins 32. When the second conveyance mechanism 42 is raised (driven in the +Z direction), the substrate 10 is passed from the lift pins 32 to the second conveyance mechanism 42, and the second conveyance mechanism 42 holds the substrate 10.

In step S206, the second conveyance mechanism 42 holding the substrate 10 is driven to the supply position LP (above the supply position LP).

In step S207, the time from completion of driving of the second conveyance mechanism 42 to the supply position LP to the start of supplying (passing) the substrate 10 from the second conveyance mechanism 42 to the substrate stage 50, that is, the waiting time in the supply position LP is measured and stored. Here, the waiting time in the supply position LP corresponds to the waiting time until supplying the substrate 10 from the second conveyance mechanism 42 to the substrate stage 50 is started in the supply position LP. The waiting time in the supply position LP is stored (memorized) in, for example, a storage unit 91 of the control unit 90.

In step S208, the substrate 10 (Nth substrate 12) is conveyed from the second conveyance mechanism 42 to the substrate stage 50. More specifically, the substrate 10 is passed from the second conveyance mechanism 42 to the substrate stage 50 by lowering (driving in the −Z direction) the second conveyance mechanism 42, and the substrate stage 50 holds the substrate 10. Note that an operation of the second conveyance mechanism 42 to supply the substrate 10 to the substrate stage 50 and an operation of the substrate stage 50 to receive the substrate 10 from the second conveyance mechanism 42 are executed in synchronization under the control of the control unit 90. This means that, in FIG. 2B, the substrate stage 50 executes the operation of receiving the substrate 10 in the supply position LP in a state in which the (N−1)th substrate 11 with the exposure sequence completed has been passed to the third conveyance mechanism 43 so the substrate stage 50 is holding no substrate 10.

In step S209, the second conveyance mechanism 42 is caused to retreat from the supply position LP. More specifically, the second conveyance mechanism 42 having supplied the substrate 10 to the substrate stage 50, that is, the second conveyance mechanism 42 holding no substrate 10 is caused to retreat from the supply position LP and driven to a conveyance preparation position for conveying an (N+1)th substrate 13.

In this embodiment, as the conveyance start condition (parameter used therefor) for starting conveyance of the substrate 10 to the substrate stage 50 between step S203 and step S204, the first time is defined. The first time is defined by a sum of the time (temperature control side preparation time) required to start conveyance of the substrate 10 to the substrate stage 50 in the temperature control mechanism 30 and the time (conveyance side preparation time) required to start conveyance of the substrate 10 to the substrate stage 50 in the second conveyance mechanism 42. The temperature control side preparation time includes the time required to cancel (OFF) holding of the substrate 10 by the holding unit 33 and the time required to raise the lift pins 32 in the temperature control mechanism 30. The conveyance side preparation time includes the time required to drive the second conveyance mechanism 42 to the position of the temperature control mechanism 30 and the time required to drive the second conveyance mechanism 42 to the supply position LP. The first time may be calculated from the driving profiles of the temperature control mechanism 30 and the second conveyance mechanism 42, or a measured value (for example, an immediately preceding measured value, or the average value of a plurality of measured values) may be used. The first time is stored (memorized) in, for example, the storage unit 91 of the control unit 90.

Next, the substrate process illustrated in FIG. 4 will be described. In step S301, the substrate stage 50 is driven to the supply position LP to receive the substrate 10 (Nth substrate 12) from the second conveyance mechanism 42.

In step S302, the substrate stage 50 receives the substrate 10 held by the second conveyance mechanism 42. More specifically, in the substrate stage 50, the lift pins 52 are raised (driven in the +Z direction) from the substrate chuck 51 to receive the substrate 10 from the second conveyance mechanism 42. Then, when the retreat of the second conveyance mechanism 42 (step S209) is completed, the lift pins 52 are lowered (driven in the −Z direction) to hold (chuck) the substrate 10 by the substrate chuck 51. At this time, as has been described above, the operation of the substrate stage 50 to receive the substrate 10 from the second conveyance mechanism 42 is executed in synchronization with the operation of the second conveyance mechanism 42 to supply the substrate 10 to the substrate stage 50. Then, the substrate stage 50 holding the substrate 10 is driven to an exposure position. Here, the exposure position is a position where the exposure process is performed with respect to the substrate 10, that is, a position below the projection optical system 7.

Note that in this embodiment, a case has been described in which the retreat of the second conveyance mechanism 42 (step S209) and the operation of passing the substrate 10 from the lift pins 52 to the substrate chuck 51 performed in the substrate stage 50 are serially executed, but the present invention is not limited to this. For example, in parallel with the retreat of the second conveyance mechanism 42 (step S209), the substrate stage 50 holding the substrate 12 with the lift pins 52 may be driven to the exposure position, and the substrate 10 may be passed from the lift pins 52 to the substrate chuck 51 while driving the substrate stage 50.

In step S303, it is determined whether the waiting time in the supply position LP stored in step S207 is within an upper limit time. The upper limit time is an upper limit time which ensures that the temperature of the substrate 10 having undergone the temperature control by the temperature control mechanism 30 is the predetermined temperature, more specifically, an upper limit time which can allow a shift of the temperature of the substrate 10 from the predetermined temperature in terms of accuracy. In this embodiment, the control unit 90 also functions as an upper limit setting unit 93 that implements a function of setting the upper limit time, and the like. In step S303, the waiting time in the supply position LP stored in step S207 is compared with the upper limit time set by the upper limit setting unit 93. If the waiting time is shorter than the upper limit time, that is, if the waiting time is within the upper limit time, the process transitions to step S304. On the other hand, if the waiting time is longer than the upper limit time, that is, if the waiting time is not within the upper limit time, the process transitions to step S306-2.

In step S304, the exposure sequence with respect to the substrate 10 held by the substrate stage 50 is started. More specifically, the alignment process and the exposure process are sequentially performed on each shot region of the substrate 10.

In step S305, for the substrate 10 with the exposure sequence started in step S304, the remaining time until the exposure sequence is completed is calculated. The remaining time can be obtained by calculation from the driving profile of the substrate stage 50, the exposure amount and luminance set by a recipe, and the number (shot number) of the shot region where the exposure sequence is being performed. Alternatively, the remaining time may be obtained from the processing time of the exposure sequence performed with respect to the preceding substrate 10 (for example, the (N−1)th substrate 11) and the shot number where the exposure sequence is being performed (for example, the shot number of the Nth substrate 12 where the exposure sequence is being performed).

In step S306-1, in order to collect, by the third conveyance mechanism 43, the substrate 10 completed with the exposure sequence, that is, the substrate 10 with the exposure sequence performed on all the shot regions, the substrate stage 50 is driven to the collection position ULP.

In step S307-1, in the substrate stage 50, the substrate 10 held by the substrate chuck 51 is passed to the lift pins 52. More specifically, holding of the substrate 10 by the substrate chuck 51 is canceled (OFF), and the lift pins 52 are raised (driven in the +Z direction). With this, the substrate 10 is passed from the substrate chuck 51 to the lift pins 52, and the lift pins 52 hold the substrate 10.

In step S308-1, the substrate 10 held by the lift pins 52 is passed to the third conveyance mechanism 43. More specifically, first, the third conveyance mechanism 43 is driven and inserted between the substrate chuck 51 and the lift pins 52. When the third conveyance mechanism 43 is raised (driven in the +Z direction), the substrate 10 is passed from the lift pins 52 to the third conveyance mechanism 43, and the third conveyance mechanism 43 holds the substrate 10.

In step S309-1, the third conveyance mechanism 43 is caused to retreat from the collection position ULP. More specifically, the third conveyance mechanism 43 holding the substrate 10 is caused to retreat from the collection position ULP, and driven to the position of the collection table 60 to collect the substrate 10. After the third conveyance mechanism 43 is caused to retreat, the substrate stage 50 is driven to the supply position LP to receive the next substrate 10 ((N+1)th substrate 13 (third substrate)) from the second conveyance mechanism 42.

In step S310-1, the substrate 10 held by the third conveyance mechanism 43 is passed to the collection table 60.

In step S311, the first conveyance mechanism 41 collects (holds) the substrate 10 conveyed to the collection table 60, and conveys it to the unloading table 22. The substrate 10 conveyed to the unloading table 22 is collected by the conveyance mechanism provided in the coating/developing apparatus 1, and the development process of developing the substrate 10 is performed.

In this embodiment, a sum of the remaining time of the exposure sequence calculated in step S305 and the time from the start of driving of the substrate stage 50 to the collection position ULP (step S306-1) to the completion of driving of the substrate stage 50 to the supply position LP (step S301) is defined as the second time. The second time is stored (memorized) in, for example, the storage unit 91 of the control unit 90.

In this embodiment, the control unit 90 uses the first time and the second time stored in the storage unit 91 to determine whether the conveyance start condition for starting conveyance of the substrate 10 to the substrate stage 50 is satisfied. More specifically, if the first time is equal to or longer than the second time, the control unit 90 determines that the conveyance start condition is satisfied. As has been described above, if the conveyance start condition is satisfied, step S204 is started to convey the substrate 10 completed with the temperature control and alignment by the temperature control mechanism 30.

In this manner, in this embodiment, by using the first time and the second time, in accordance with the progress of the exposure sequence with respect to the preceding substrate 10 ((N−1)th substrate 11), the start of conveyance of the succeeding substrate 10 (Nth substrate 12) waiting in the temperature control mechanism 30 is controlled. Note that the start of conveyance of the succeeding substrate 10 corresponds to the start of step S204 illustrated in FIG. 3. Accordingly, for all the substrates 10 in a lot, the time from conveying the substrate 10 from the temperature control mechanism 30 to holding the substrate 10 by the substrate stage 50 can be made constant. With this, the temperature of the substrate 10 upon supplying (passing) the substrate 10 to the substrate stage 50 can be made constant (predetermined temperature) among the substrates in a lot. As a result, in the exposure apparatus 100, variation of the temperature of the substrate 10 upon supplying the substrate 10 to the substrate stage 50 is reduced, so that the alignment accuracy and the overlay accuracy can be improved. Further, in this embodiment, since the substrate stage 50 is not made to wait in the supply position LP, it is possible to achieve the throughput similar to that in a conventional technique which makes the succeeding substrate 10 wait in the supply position LP.

Note that, if there is no preceding substrate 10, that is, for the first substrate 10 in a lot, the second time does not exist. Therefore, if the temperature control and alignment of the substrate 10 by the temperature control mechanism 30 are completed, it is determined that the conveyance start condition is satisfied, and step S204 is started.

Next, a case will be described in which, in step S303, the waiting time in the supply position LP stored in step S207 is compared with the upper limit time set by the upper limit setting unit 93, and the waiting time is longer than the upper limit time, that is, the waiting time is not within the upper limit time. This can be, for example, a case in which the substrate stage 50 is stopped due to an error or temporary stop of the exposure sequence with respect to the preceding substrate 10 ((N−1)th substrate 11). An example of the error which causes the substrate stage 50 to stop is a case in which the positional shift from the target position (six axes in the X, Y, Z directions and rotation directions about respective axes) of the substrate stage 50 exceeds an allowable value.

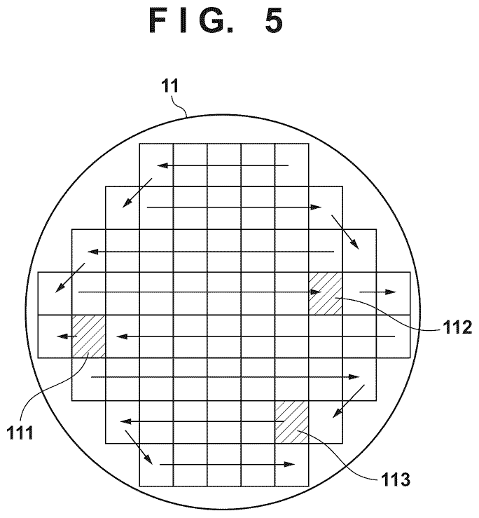

FIG. 5 is a view showing the layout (shot layout) of the shot regions of the substrate 10, for example, the (N−1)th substrate 11. In FIG. 5, arrows indicate the order of the exposure sequence of the respective shot regions, and indicate that the exposure sequence is started from the top right shot region and the exposure sequence is performed while reversing the step direction in the X direction in each row. For example, let a shot region 111 be the shot region where the first time becomes equal to or longer than the second time. In this case, when the exposure sequence with respect to the shot region 111 is completed, the conveyance start condition is satisfied, and conveyance of the substrate 10 completed with the temperature control and alignment by the temperature control mechanism 30 is started.

Here, assume that the substrate stage 50 stops due to an error in the exposure sequence in a shot region 112. In this case, since the shot region 112 is a shot region where the exposure sequence is performed before the shot region 111 and the succeeding substrate 10 (Nth substrate 12) is waiting in the temperature control mechanism 30, it is kept waiting in the temperature control mechanism 30. Then, when the exposure sequence is restarted and the exposure sequence with respect to the shot region 111 is completed, it is determined that the conveyance start condition is satisfied, and conveyance of the succeeding substrate 10 (Nth substrate 12) waiting in the temperature control mechanism 30 is started.

On the other hand, assume that the substrate stage 50 stops due to an error in the exposure sequence in a shot region 113. In this case, since the shot region 113 is a shot region where the exposure sequence is performed after the shot region 111, it has already been determined that the conveyance start condition is satisfied and conveyance of the succeeding substrate 10 (Nth substrate 12) from the temperature control mechanism 30 has been started. However, since the exposure sequence with respect to the preceding substrate 10 stops or continues, the substrate stage 50 is not in the supply position LP so that the succeeding substrate 10 conveyed from the temperature control mechanism 30 to the supply position LP is made to wait in the supply position LP. If the exposure sequence is restarted in this state, since the succeeding substrate 10 has waited in the supply position LP, the temperature of the substrate 10 upon supplying the substrate 10 to the substrate stage 50 may have fluctuated from the predetermined temperature beyond the allowable range.

Therefore, in this embodiment, as has been described above, the waiting time in the supply position LP stored in step S207 is compared with the upper limit time set by the upper limit setting unit 93 (step S303). If the waiting time is longer than the upper limit time, this is considered to lead to deterioration of the alignment accuracy and the overlay accuracy, so the process does not transition to the exposure sequence (step S304) but transitions to step S306-2. In step S306-2, the substrate stage 50 hold the substrate 10 in step S302 is driven from the exposure position to the collection position ULP.

Steps S307-2 to S310-2 are similar to steps S307-1 to S310-1 except for whether or not the substrate 10 to be conveyed has undergone the exposure sequence, so a detailed description will be omitted here.

In step S312, the substrate 10 (Nth substrate 12 (unexposed)) conveyed to the collection table 60 is collected (held) by the first conveyance mechanism 41 and conveyed to a temporary retreat unit 70. The temporary retreat unit 70 has a function of temporarily causing the substrate 10 to retreat from the conveyance path of the substrate 10 by the conveyance mechanism including the first conveyance mechanism 41, the second conveyance mechanism 42, and the third conveyance mechanism 43. For the temporary retreat unit 70, for example, a container called a Front Opening Unified Pod (FOUP) capable of storing a plurality of the substrates 10 can be used.

In step S313, in order to perform the exposure sequence with respect to the substrate 10 (Nth substrate 12 (unexposed)) conveyed to the temporary retreat unit 70, the first conveyance mechanism 41 holds the substrate 10 conveyed to the temporary retreat unit 70 and conveys it to the alignment mechanism 20 again. With this, the steps from step S201 are sequentially performed with respect to the substrate 10 conveyed to the temporary retreat unit 70, and the process transitions to the exposure sequence. Note that the re-conveyance of the substrate 10 from the temporary retreat unit 70 to the alignment mechanism 20 (step S313) may be performed while setting the substrate 10 as the Nth or last substrate in the lot, or may be performed (inserted) while setting the substrate 10 as the (N+1)th or subsequent substrate in the succeeding lot.

In this manner, in this embodiment, if the waiting time of the substrate 10 in the supply position LP is longer than the upper limit time set by the upper limit setting unit 93, the substrate 10 is conveyed to the temperature control mechanism 30 via the substrate stage 50 to undergo temperature control by the temperature control mechanism 30 again. Then, in order to perform the exposure sequence with respect to the substrate 10 having undergone the temperature control by the temperature control mechanism 30 again, the substrate 10 is re-conveyed from the temperature control mechanism 30 to the substrate stage 50. Thus, for all the substrates 10 in a lot, the time from conveying the substrate 10 from the temperature control mechanism 30 to holding the substrate 10 by the substrate stage 50 can be made constant. With this, the temperature of the substrate 10 upon conveying (passing) the substrate 10 to the substrate stage 50 can be made constant (predetermined temperature) among the substrates in a lot. As a result, in the exposure apparatus 100, variation of the temperature of the substrate 10 upon conveying the substrate 10 to the substrate stage 50 can be reduced, and the alignment accuracy and the overlay accuracy can be improved.

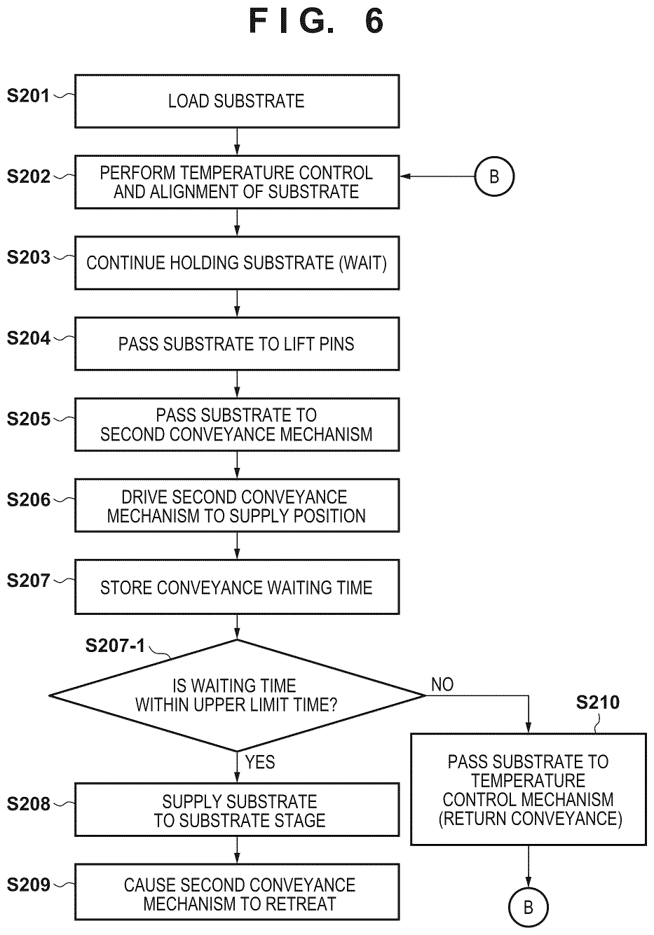

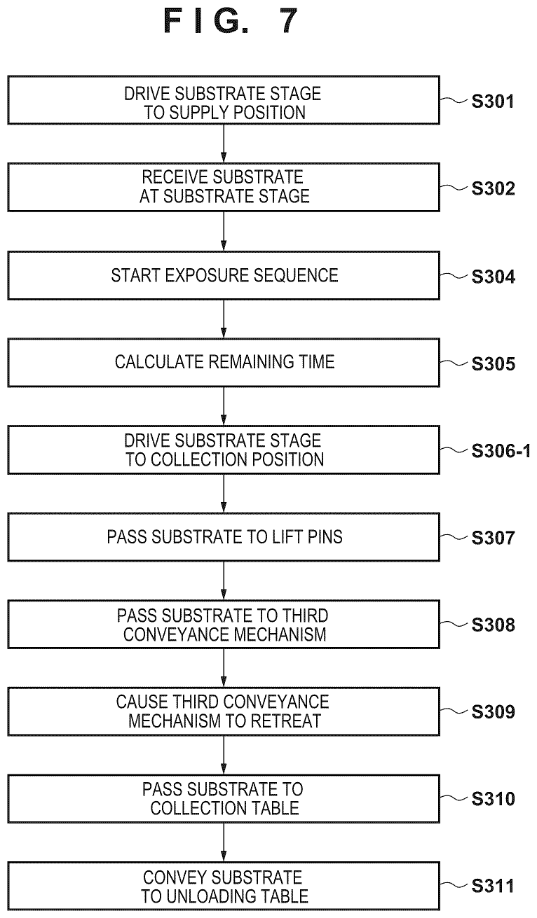

Alternatively, as illustrated in FIGS. 6 and 7, if the waiting time of the substrate 10 in the supply position LP is larger than the upper limit time set by the upper limit setting unit 93, it is also possible to convey the substrate 10 to the temperature control mechanism 30 without intervening the substrate stage 50 to perform temperature control again. FIG. 6 is a flowchart for describing a process (conveyance process) from loading the substrate 10 from the coating/developing apparatus 1 to the exposure apparatus 100 to conveying the substrate 10 to the substrate stage 50. FIG. 7 is a flowchart for describing a process (substrate process) of holding the substrate 10 by the substrate stage 50 and performing exposure. Note that steps of FIGS. 6 and 7 similar to those of FIGS. 3 and 4 are denoted by the same reference numerals, and a detailed description will be omitted here. Differences will mainly be described.

First, the conveyance process illustrated in FIG. 6 will be described. In step S207-1, it is determined whether the waiting time in the supply position LP stored in step S207 is within the upper limit time. The waiting time in the supply position LP stored in step S207 is compared with the upper limit time set by the upper limit setting unit 93. If the waiting time is shorter than the upper limit time, that is, if the waiting time is within the upper limit time, the process transitions to step S208. On the other hand, if the waiting time is longer than the upper limit time, that is, if the waiting time is not within the upper limit time, the process transitions to step S210.

In step S210, the substrate 10 (Nth substrate 12) waiting in the supply position LP is passed from the second conveyance mechanism 42 to the temperature control mechanism 30 without intervening the substrate stage 50. More specifically, the second conveyance mechanism 42 holding the substrate 10 is driven (returned) to the position of the temperature control mechanism 30 to pass the substrate 10 to the temperature control mechanism 30. In other words, a return conveyance is executed in which the conveyance of the substrate 10 shown in steps S204 to S206 is performed in the reverse order. The substrate 10 returned to the temperature control mechanism 30 is held by the holding unit 33, and temperature control (re-control of temperature) by the temperature control unit 31 and alignment (re-alignment) by the driving mechanism are performed (that is, the steps from step S202 are sequentially performed).

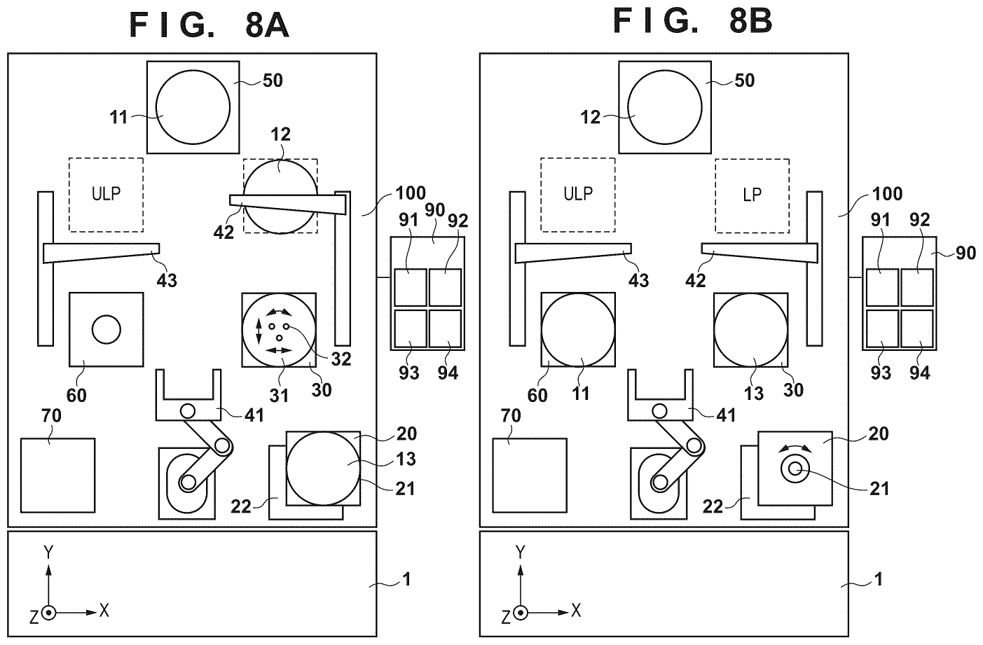

Note that, in order to return the substrate 10 (Nth substrate 12 (first substrate)) waiting in the supply position LP to the temperature control mechanism 30 by the return conveyance, no substrate 10 should be in the temperature control mechanism 30 as shown in FIG. 8A. Therefore, to maintain the state in which no substrate 10 is in the temperature control mechanism 30, the succeeding substrate 10 ((N+1)th substrate 13 (third substrate)) is held by the alignment mechanism 20 or the first conveyance mechanism 41 until the preceding substrate 10 is normally conveyed to the substrate stage 50.

To achieve this, in this embodiment, the control unit 90 also functions as a conveyance determination unit 94 that determines whether the substrate 10 is normally conveyed from the second conveyance mechanism 42 to the substrate stage 50. The conveyance determination unit 94 determines whether the substrate 10 is normally conveyed from the second conveyance mechanism 42 to the substrate stage 50 based on the holding force of the substrate 10 by at least one of the second conveyance mechanism 42, the lift pins 52, and the substrate chuck 51, that is, the chucking pressure value of the substrate 10. For example, if the substrate 10 is normally conveyed from the second conveyance mechanism 42 to the substrate stage 50, the chucking pressure values of the second conveyance mechanism 42, the lift pins 52, and the substrate chuck 51 change as follows. First, the chucking pressure value of the second conveyance mechanism 42 becomes equal to or smaller than a threshold value, the chucking pressure value of the lift pins 52 exceeds a threshold value and then becomes equal to or smaller than the threshold value, and the chucking pressure value of the substrate chuck 51 exceeds a threshold value. If the conveyance determination unit 94 determines that the substrate 10 (Nth substrate 12) is normally conveyed from the second conveyance mechanism 42 to the substrate stage 50, the succeeding substrate 10 ((N+1)th substrate 13) is conveyed to the temperature control mechanism 30 as shown in FIG. 8B, and the steps from step S202 are sequentially performed.

Next, the substrate process illustrated in FIG. 7 will be described. The substrate process illustrated in FIG. 7 is a process with steps S303, S306-2 to S310-2, S312, and S313 removed from the substrate process illustrated in FIG. 4. This is because, as has been described above, determination as to whether the waiting time in the supply position LP stored in step S207 is within the upper limit time is performed not after the substrate 10 is passed to the substrate stage 50 but before the substrate 10 is passed to the substrate stage 50.

In this manner, in this embodiment, if the waiting time of the substrate 10 in the supply position LP is longer than the upper limit time set by the upper limit setting unit 93, the substrate 10 is conveyed to the temperature control mechanism 30 without intervening the substrate stage 50 to undergo temperature control by the temperature control mechanism 30 again. At this time, for the substrate 10 conveyed to the temperature control mechanism 30, the return conveyance is executed in which the conveyance of the substrate 10 shown in steps S204 to S206 is performed in the reverse order to return the substrate 10 to the temperature control mechanism 30. To maintain the state in which no substrate 10 is in the temperature control mechanism 30, the succeeding substrate 10 ((N+1)th substrate 13) is held by the alignment mechanism 20 or the first conveyance mechanism 41 until the preceding substrate 10 (Nth substrate 12) is normally conveyed to the substrate stage 50. Thus, for all the substrates 10 in a lot, the time from conveying the substrate 10 from the temperature control mechanism 30 to holding the substrate 10 by the substrate stage 50 can be made constant. With this, the temperature of the substrate 10 upon conveying (passing) the substrate 10 to the substrate stage 50 can be made constant (predetermined temperature) among the substrates in a lot. As a result, in the exposure apparatus 100, variation of the temperature of the substrate 10 upon conveying the substrate 10 to the substrate stage 50 can be reduced, and the alignment accuracy and the overlay accuracy can be improved.

### Second Embodiment

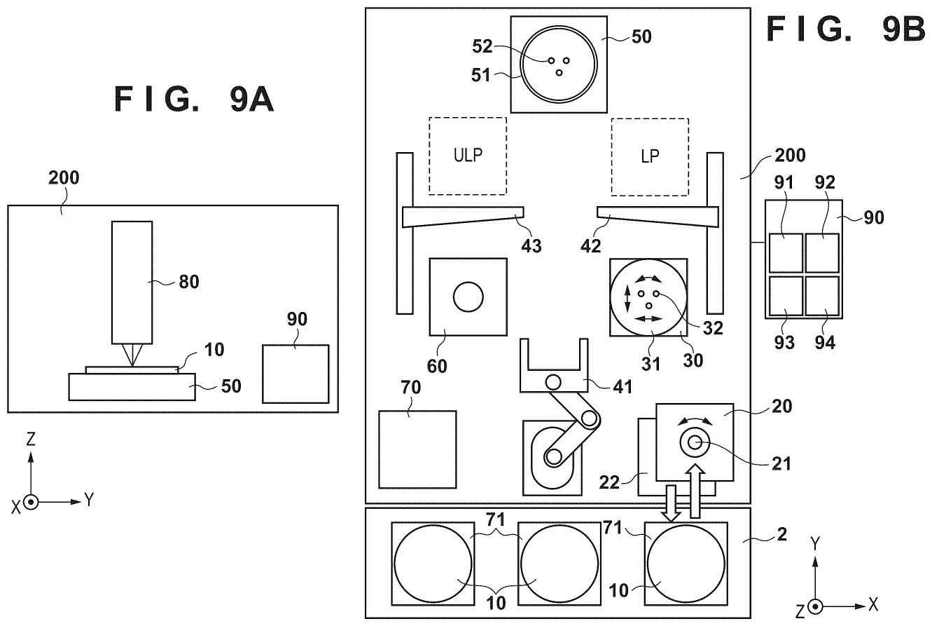

FIGS. 9A and 9B are views for describing a measurement apparatus 200 as a substrate processing apparatus in the second embodiment of the present invention. The measurement apparatus 200 is an alignment measurement apparatus that measures the position of a mark provided in a layer (target layer) serving as the reference of a substrate. A substrate 10 is a measurement target object where the measurement apparatus 200 measures the array (shape thereof) of a plurality of shot regions of the substrate 10 and the shape of each shot region. The substrate 10 is a substrate used to manufacture a device such as a semiconductor element or a liquid crystal display device, and includes a wafer, a glass substrate, another processing target substrate, or the like.

As shown in FIG. 9A, the measurement apparatus 200 includes a substrate stage 50, an alignment optical system 80, and a control unit 90. The alignment optical system 80 has a function as a measurement device that detects an alignment mark provided in the substrate 10 and measures the position of the alignment mark (that is, measures the position of the substrate 10), as has been described above. In the manufacturing process of a device, in order to implement a high alignment accuracy even if a distortion occurs in the array of the shot regions of the substrate 10 (substrate distortion), it is necessary to measure the positions of a large number of alignment marks provided in the substrate 10.

However, if the alignment optical system 80 of the exposure apparatus 100 measures the positions of the large number of alignment marks, a long time is required for the measurement (alignment measurement) so that the productivity of the exposure apparatus 100 deteriorates. Therefore, a technique is proposed in which the measurement apparatus 200 different from the exposure apparatus 100 measures, in advance, the positions of the large number of alignment marks provided in the substrate 10, and the substrate 10 is exposed considering the measurement result.

Here, with reference to FIG. 9B, the sequence of conveyance of the substrate 10 between the measurement apparatus 200 and a cassette station 2 will be described. The measurement apparatus 200 is connected to the cassette station 2 that has a function of placing a plurality of substrate cassettes 71. Connection between the measurement apparatus 200 and the cassette station 2 is usually called in-line connection. The cassette station 2 includes, for example, an Equipment Front End Module (EFEM). The substrate cassette 71 includes, for example, a Front Opening Unified Pod (FOUP).

In this embodiment, the arrangement on the conveyance path of the substrate 10 in the measurement apparatus 200 is the same as the arrangement on the conveyance path of the substrate 10 in the exposure apparatus 100 described in the first embodiment. The measurement apparatus 200 is different from the exposure apparatus 100 mainly in two points. The first point is that the process to be performed on the substrate 10 held by the substrate stage 50 is not the exposure process (exposure sequence) but a measurement process (measurement sequence) of measuring the position of the alignment mark provided in the substrate 10. The second point is that the conveyance source and conveyance destination of the substrate 10 are not the coating/developing apparatus 1 but the cassette station 2.

In this embodiment, the process (conveyance process) from loading of the substrate 10 from the cassette station 2 to the measurement apparatus 200 to conveying the substrate 10 to the substrate stage 50 is similar to that in the first embodiment (FIGS. 3 and 6). More specifically, it is only necessary to replace the coating/developing apparatus 1 with the cassette station 2. Therefore, a detailed description will be omitted here.

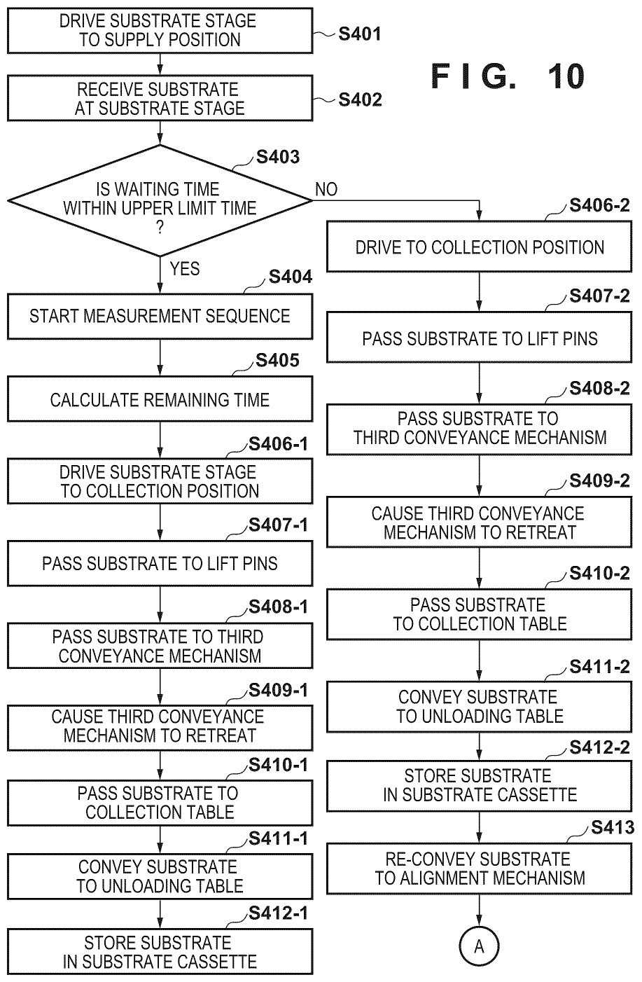

FIG. 10 is a flowchart for describing a process (substrate process) of holding the substrate 10 by the substrate stage 50 and measuring the position of the alignment mark. The substrate process illustrated in FIG. 10 partially overlaps the substrate process illustrated in FIGS. 4 and 7 (first embodiment), but the measurement sequence is different from the exposure sequence. Therefore, respective steps will be described.

In step S401, the substrate stage 50 is driven to a supply position LP to receive the substrate 10 (Nth substrate 12) from a second conveyance mechanism 42.

In step S402, the substrate stage 50 receives the substrate 10 held by the second conveyance mechanism 42. More specifically, in the substrate stage 50, lift pins 52 are raised (driven in the +Z direction) from a substrate chuck 51 to receive the substrate 10 from the second conveyance mechanism 42. Then, when the retreat of the second conveyance mechanism 42 is completed, the lift pins 52 are lowered (driven in the −Z direction) to hold (chuck) the substrate 10 by the substrate chuck 51. At this time, the operation of the substrate stage 50 to receive the substrate 10 from the second conveyance mechanism 42 is executed in synchronization with the operation of the second conveyance mechanism 42 to supply the substrate 10 to the substrate stage 50. Then, the substrate stage 50 holding the substrate 10 is driven to a measurement position. Here, the measurement position is a position where the measurement process is performed with respect to the substrate 10, that is, a position below the alignment optical system 80.

Note that in this embodiment, a case has been described in which the retreat of the second conveyance mechanism 42 and the operation of passing the substrate 10 from the lift pins 52 to the substrate chuck 51 performed in the substrate stage 50 are serially executed, but the present invention is not limited to this. For example, in parallel with the retreat of the second conveyance mechanism 42, the substrate stage 50 holding the substrate 12 with the lift pins 52 may be driven to the measurement position, and the substrate 10 may be passed from the lift pins 52 to the substrate chuck 51 while driving the substrate stage 50.

In step S403, as in step S303, it is determined whether the waiting time in the supply position LP stored in a storage unit 91 of the control unit 90 is within an upper limit time. In step S403, the waiting time in the supply position LP stored in the storage unit 91 of the control unit 90 is compared with the upper limit time set by an upper limit setting unit 93. If the waiting time is shorter than the upper limit time, that is, if the waiting time is within the upper limit time, the process transitions to step S404. On the other hand, if the waiting time is longer than the upper limit time, that is, if the waiting time is not within the upper limit time, the process transitions to step S406-2.

In step S404, the measurement sequence with respect to the substrate 10 held by the substrate stage 50 is started. More specifically, the measurement sequence includes a measurement process of measuring the position of the substrate 10 (so-called prealignment and global alignment), and a measurement process of measuring the position of the alignment mark provided in each shot region of the substrate 10 (so-called nonlinear alignment).

In step S405, for the substrate 10 with the measurement sequence started in step S404, the remaining time until the measurement sequence is completed is calculated. The remaining time can be obtained by calculation from the driving profile of the substrate stage 50, the measurement time (image capturing time) of the alignment mark, and the number (shot number) of the shot region where the measurement sequence is being performed. Alternatively, the remaining time may be obtained from the processing time of the measurement sequence performed with respect to the preceding substrate 10 (for example, (N−1)th substrate 11) and the shot number where the measurement sequence is being performed (for example, the shot number of the Nth substrate 12 where the measurement sequence is being performed).

In step S406-1, in order to collect, by a third conveyance mechanism 43, the substrate 10 completed with the measurement sequence, that is, the substrate 10 with the measurement sequence performed on all the shot regions, the substrate stage 50 is driven to a collection position ULP.

In step S407-1, in the substrate stage 50, the substrate 10 held by the substrate chuck 51 is passed to the lift pins 52. More specifically, holding of the substrate 10 by the substrate chuck 51 is canceled (OFF), and the lift pins 52 are raised (driven in the +Z direction). With this, the substrate 10 is passed from the substrate chuck 51 to the lift pins 52, and the lift pins 52 hold the substrate 10.

In step S408-1, the substrate 10 held by the lift pins 52 is passed to the third conveyance mechanism 43. More specifically, first, the third conveyance mechanism 43 is driven and inserted between the substrate chuck 51 and the lift pins 52. When the third conveyance mechanism 43 is raised (driven in the +Z direction), the substrate 10 is passed from the lift pins 52 to the third conveyance mechanism 43, and the third conveyance mechanism 43 holds the substrate 10.

In step S409-1, the third conveyance mechanism 43 is caused to retreat from the collection position ULP. More specifically, the third conveyance mechanism 43 holding the substrate 10 is caused to retreat from the collection position ULP, and driven to the position of a collection table 60 to collect the substrate 10. After the third conveyance mechanism 43 is caused to retreat, the substrate stage 50 is driven to the supply position LP to receive the next substrate 10 ((N+1)th substrate 13 (third substrate)) from the second conveyance mechanism 42.

In step S410-1, the substrate 10 held by the third conveyance mechanism 43 is passed to the collection table 60.

In step S411-1, a first conveyance mechanism 41 collects (holds) the substrate 10 conveyed to the collection table 60, and conveys it to an unloading table 22.

In step S412-1, the substrate 10 conveyed to the unloading table 22 is collected (held) by a conveyance mechanism provided in the cassette station 2 and stored in the substrate cassette 71 (designated slot thereof) as the conveyance source.

In this embodiment, the sum of the remaining time of the measurement sequence calculated in step S405 and the time from the start of driving of the substrate stage 50 to the collection position ULP (step S406-1) to the completion of driving of the substrate stage 50 to the supply position LP (step S401) is defined as the second time. The second time is stored (memorized) in, for example, the storage unit 91 of the control unit 90.

In this embodiment, the control unit 90 uses the first time and the second time stored in the storage unit 91 to determine whether the conveyance start condition for starting conveyance of the substrate 10 to the substrate stage 50 is satisfied. More specifically, if the first time is equal to or longer than the second time, the control unit 90 determines that the conveyance start condition is satisfied. As has been described above, if the conveyance start condition is satisfied, it is started to convey the substrate 10 completed with the temperature control and alignment by a temperature control mechanism 30.

In this manner, in this embodiment, by using the first time and the second time, in accordance with the progress of the measurement sequence with respect to the preceding substrate 10 ((N−1)th substrate 11), the start of conveyance of the succeeding substrate 10 (Nth substrate 12) waiting in the temperature control mechanism 30 is controlled. Accordingly, for all the substrates 10 in a lot, the time from conveying the substrate 10 from the temperature control mechanism 30 to holding the substrate 10 by the substrate stage 50 can be made constant. With this, the temperature of the substrate 10 upon supplying (passing) the substrate 10 to the substrate stage 50 can be made constant (predetermined temperature) among the substrates in a lot. As a result, in the measurement apparatus 200, variation of the temperature of the substrate 10 upon supplying the substrate 10 to the substrate stage 50 is reduced. Hence, in the measurement sequence, the accuracy of measuring the array of the plurality of shot regions of the substrate 10 and the shape of each shot region can be improved. Further, in this embodiment, since the substrate stage 50 is not made to wait in the supply position LP, it is possible to achieve the throughput similar to that in a conventional technique which makes the succeeding substrate 10 wait in the supply position LP.

Note that, if there is no preceding substrate 10, that is, for the first substrate 10 in a lot, the second time does not exist. Therefore, if the temperature control and alignment of the substrate 10 by the temperature control mechanism 30 are completed, it is determined that the conveyance start condition is satisfied, and conveyance of the substrate 10 from the temperature control mechanism 30 is started.

Next, a case will be described in which, in step S403, the waiting time in the supply position LP stored in the storage unit 91 of the control unit 90 is compared with the upper limit time set by the upper limit setting unit 93, and the waiting time is longer than the upper limit time, that is, the waiting time is not within the upper limit time. This can be, for example, a case in which the substrate stage 50 is stopped due to an error or temporary stop of the measurement sequence with respect to the preceding substrate 10 ((N−1)th substrate 11). Examples of the error which causes the substrate stage 50 to stop is a case in which the alignment mark serving as the measurement target does not exist, and a case in which the measurement value of the alignment mark is an abnormal value.

In FIG. 5, assume that the alignment mark serving as the measurement target exists in the center of each shot region. Arrows shown in FIG. 5 indicate the order of the measurement sequence of the respective shot regions, and indicate that the measurement sequence is started from the top right shot region and the measurement sequence is performed while reversing the step direction in the X direction in each row. For example, let a shot region 111 be the shot region where the first time becomes equal to or longer than the second time. In this case, when the measurement sequence with respect to the shot region 111 is completed, the conveyance start condition is satisfied, and conveyance of the substrate 10 completed with the temperature control and alignment by the temperature control mechanism 30 is started.

Here, assume that the substrate stage 50 stops due to an error in the measurement sequence in a shot region 112. In this case, since the shot region 112 is a shot region where the measurement sequence is performed before the shot region 111 and the succeeding substrate 10 (Nth substrate 12) is waiting in the temperature control mechanism 30, it is kept waiting in the temperature control mechanism 30. Then, when the measurement sequence is restarted and the measurement sequence with respect to the shot region 111 is completed, it is determined that the conveyance start condition is satisfied, and conveyance of the succeeding substrate 10 (Nth substrate 12) waiting in the temperature control mechanism 30 is started.

On the other hand, assume that the substrate stage 50 stops due to an error in the measurement sequence in a shot region 113. In this case, since the shot region 113 is a shot region where the measurement sequence is performed after the shot region 111, it has already been determined that the conveyance start condition is satisfied and conveyance of the succeeding substrate 10 (Nth substrate 12) from the temperature control mechanism 30 has been started. However, since the measurement sequence with respect to the preceding substrate 10 stops or continues, the substrate stage 50 is not in the supply position LP so that the succeeding substrate 10 conveyed from the temperature control mechanism 30 to the supply position LP is made to wait in the supply position LP. If the measurement sequence is restarted in this state, since the succeeding substrate 10 has waited in the supply position LP, the temperature of the substrate 10 upon supplying the substrate 10 to the substrate stage 50 may have fluctuated from the predetermined temperature beyond the allowable range.

Therefore, in this embodiment, as has been described above, the waiting time in the supply position LP stored in the storage unit 91 of the control unit 90 is compared with the upper limit time set by the upper limit setting unit 93 (step S403). If the waiting time is longer than the upper limit time, this is considered to lead to deterioration of the measurement accuracy in the measurement sequence, so the process does not transition to the measurement sequence (step S404) but transitions to step S406-2. In step S406-2, the substrate stage 50 made to hold the substrate 10 in step S402 is driven from the measurement position to the collection position ULP.

Steps S407-2 to S412-2 are similar to steps S407-1 to S412-1 except for whether or not the substrate 10 to be conveyed has undergone the measurement sequence, so a detailed description will be omitted here.

In step S413, in order to perform the measurement sequence with respect to the substrate 10 (Nth substrate 12 (unmeasured)) stored in the substrate cassette 71, the conveyance mechanism provided in the cassette station 2 holds the substrate 10 and conveys it to the alignment mechanism 20 again. With this, steps for the temperature control and alignment by the temperature control mechanism 30 and the like are sequentially performed with respect to the substrate 10 stored in the substrate cassette 71, and the process transitions to the measurement sequence. Note that the re-conveyance of the substrate 10 from the substrate cassette 71 to the alignment mechanism 20 (step S413) may be performed while setting the substrate 10 as the Nth or last substrate in the lot, or may be performed (inserted) while setting the substrate 10 as the (N+1)th or subsequent substrate in the succeeding lot.

In this manner, in this embodiment, if the waiting time of the substrate 10 in the supply position LP is longer then the upper limit time set by the upper limit setting unit 93, the substrate 10 undergoes the temperature control by the temperature control mechanism 30 again. More specifically, without performing the measurement sequence with respect to the substrate 10, the substrate 10 is conveyed (returned) from the supply position LP to the substrate cassette 71 via the substrate stage 50, and stored therein. Then, the substrate 10 stored in the substrate cassette 71 is re-conveyed to the temperature control mechanism 30, and the substrate 10 is re-conveyed from the temperature control mechanism 30 to the substrate stage 50 to perform the measurement sequence with respect to the substrate 10 having undergone the temperature control by the temperature control mechanism 30 again. Accordingly, for all the substrates 10 in a lot, the time from conveying the substrate 10 from the temperature control mechanism 30 to holding the substrate 10 by the substrate stage 50 can be made constant. With this, the temperature of the substrate 10 upon supplying (passing) the substrate 10 to the substrate stage 50 can be made constant (predetermined temperature) among the substrates in a lot. As a result, in the measurement apparatus 200, variation of the temperature of the substrate 10 upon supplying the substrate 10 to the substrate stage 50 can be reduced. Hence, in the measurement sequence, the accuracy of measuring the array of the plurality of shot regions of the substrate 10 and the shape of each shot region can be improved.

In this embodiment, if the waiting time of the substrate 10 in the supply position LP is longer than the upper limit time set by the upper limit setting unit 93, the substrate 10 is returned to the substrate cassette 71 and then re-conveyed to the temperature control mechanism 30. However, the substrate 10 may be not returned to the substrate cassette 71 but conveyed to a temporary retreat unit 70 and then re-conveyed to the temperature control mechanism 30, as described in the first embodiment. Furthermore, in this embodiment, the substrate 10 is re-conveyed to the temperature control mechanism 30 via the substrate stage 50, but may be re-conveyed (directly returned) to the temperature control mechanism 30 without intervening the substrate stage 50 as described in the first embodiment.

### Third Embodiment

An article manufacturing method according to an embodiment of the present invention is suitable for manufacturing an article, for example, a device (a semiconductor device, magnetic storage medium, liquid crystal element, or the like). This manufacturing method includes a step of forming a pattern on a substrate by using the exposure apparatus 100 (or the measurement apparatus 200), a step of processing the substrate on which the pattern has been formed, and a step of manufacturing an article from the processed substrate. This manufacturing method can further include other known steps (oxidation, deposition, vapor deposition, doping, planarization, etching, resist removal, dicing, bonding, packaging, and the like). The article manufacturing method according to this embodiment is advantageous in at least one of the performance, the quality, the productivity, and the production cost of the article, as compared to a conventional method.)

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2023-085705 filed on May 24, 2023, which is hereby incorporated by reference herein in its entirety.

What is claimed is:

1. A substrate processing apparatus for performing a process of a substrate, comprising:
a substrate stage configured to hold a substrate when the process is performed;
a temperature control mechanism configured to hold a substrate to be conveyed to the substrate stage and perform temperature control to a predetermined temperature;
a conveyance mechanism configured to convey a substrate in the apparatus; and
a control unit configured to control conveyance of a substrate in the apparatus,
wherein
when a first time required to convey, by the conveyance mechanism, a first substrate having undergone temperature control by the temperature control mechanism from the temperature control mechanism to a supply position where a substrate is supplied to the substrate stage becomes not less than a second time required to drive the substrate stage holding a second substrate, on which the process is being performed prior to the first substrate, to the supply position via a collection position where the processed substrate is collected, the control unit starts conveyance of the first substrate from the temperature control mechanism to the substrate stage by the conveyance mechanism, and
when a waiting time until the first substrate conveyed to the supply position is supplied to the substrate stage exceeds an upper limit time set in advance, the control unit conveys the first substrate from the supply position to the temperature control mechanism by the conveyance mechanism.

2. The apparatus according to claim 1, wherein
when the waiting time exceeds the upper limit time, the control unit conveys the first substrate from the supply position to the temperature control mechanism via the substrate stage by the conveyance mechanism.

3. The apparatus according to claim 2, wherein
when the waiting time exceeds the upper limit time, the process is not performed on the first substrate held by the substrate stage.

4. The apparatus according to claim 2, further comprising
a retreat unit configured to cause a substrate to retreat from a substrate conveyance path by the conveyance mechanism,
wherein when the waiting time exceeds the upper limit time, the control unit conveys the first substrate from the substrate stage to the temperature control mechanism via the retreat unit by the conveyance mechanism.

5. The apparatus according to claim 4, wherein
the retreat unit includes a container configured to store a substrate.

6. The apparatus according to claim 1, wherein
when the waiting time exceeds the upper limit time, the control unit conveys the first substrate from the supply position to the temperature control mechanism without intervening the substrate stage by the conveyance mechanism.

7. The apparatus according to claim 6, wherein
the control unit
determines whether the first substrate is normally supplied from the supply position to the substrate stage, and
when the first substrate is normally supplied from the supply position to the substrate stage, conveys a third substrate, on which the process is performed after the first substrate, to the temperature control mechanism by the conveyance mechanism.

8. The apparatus according to claim 1, wherein
when the waiting time exceeds the upper limit time, the temperature control mechanism performs temperature control to the predetermined temperature again with respect to the first substrate conveyed from the supply position by the conveyance mechanism.

9. The apparatus according to claim 1, wherein
the second time is defined by a sum of a remaining time of the process being performed on the second substrate held by the substrate stage and a time from a start of driving of the substrate stage holding the second substrate having undergone the process to the collection position to completion of driving of the substrate stage to the supply position.

10. The apparatus according to claim 1, wherein
the first time is defined by a sum of a time required to start conveyance of the first substrate to the substrate stage in the temperature control mechanism and a time required to start conveyance of the first substrate to the substrate stage in the conveyance mechanism.

11. The apparatus according to claim 1, wherein
the temperature control mechanism includes a holding unit configured to hold a substrate, a temperature control unit configured to adjust a temperature of a substrate held by the holding unit, and a driving mechanism configured to drive the holding unit to align a substrate.

12. The apparatus according to claim 1, wherein
the process includes an exposure process of exposing a substrate using an original to transfer a pattern of the original to the substrate.

13. The apparatus according to claim 1, wherein
the process includes a measurement process of measuring a position of a mark provided in a substrate.

14. A substrate processing method of performing a process of a substrate, comprising:
controlling conveyance of a substrate in a substrate processing apparatus that includes a substrate stage configured to hold a substrate when the process is performed, a temperature control mechanism configured to hold a substrate to be conveyed to the substrate stage and perform temperature control to a predetermined temperature, and a conveyance mechanism configured to convey a substrate,
wherein, in the controlling,
when a first time required to convey, by the conveyance mechanism, a first substrate having undergone temperature control by the temperature control mechanism from the temperature control mechanism to a supply position where a substrate is supplied to the substrate stage becomes not less than a second time required to drive the substrate stage holding a second substrate, on which the process is being performed prior to the first substrate, to the supply position via a collection position where the processed substrate is collected, conveyance of the first substrate from the temperature control mechanism to the substrate stage by the conveyance mechanism is started, and
when a waiting time until the first substrate conveyed to the supply position is supplied to the substrate stage exceeds an upper limit time set in advance, the first substrate is conveyed from the supply position to the temperature control mechanism by the conveyance mechanism.

15. An article manufacturing method comprising:
forming a pattern on a substrate using a substrate processing apparatus according to claim 12;
processing the substrate on which the pattern is formed in the forming; and
manufacturing an article from the processed substrate.
